(19) United States
(12) Patent Application Publication
(10) Pub. No.: US 2018/0315672 A1
(43) Pub. Date: Nov. 1, 2018

(54) SACRIFICIAL TEST PADS FOR INLINE TEST ACCESS

(71) Applicant: QUALCOMM Incorporated, San Diego, CA (US)

(72) Inventors: Amer Christophe CASSIER, San Diego, CA (US); Charles PAYNTER, Encinitas, CA (US)

(21) Appl. No.: 15/661,453

(22) Filed: Jul. 27, 2017

Related U.S. Application Data
(60) Provisional application No. 62/490,434, filed on Apr. 26, 2017.

(51) Int. Cl. H01L 21/66; H01L 23/00

(52) U.S. Cl. CPC H01L 22/32; H01L 24/06; H01L 22/14; H01L 21/6835; H01L 2224/06181; H01L 2224/06515; H01L 2224/0401; H01L 24/97

(57) ABSTRACT

A chip assembly includes a first die pad on a first side of the chip assembly, the first side obscured and inaccessible during testing of the chip assembly. The first side of the chip assembly is obscured and inaccessible during testing of the chip assembly. The chip assembly also includes a second die pad on a second side of the chip assembly, opposite the first side. The chip assembly further includes a portion of a sacrificial test pad on a sidewall of the chip assembly and electrically connected to the first die pad.

### CROSS-REFERENCE TO RELATED APPLICATION

The present application claims the benefit of U.S. Provisional Patent Application No. 62/490,434, filed on Apr. 26, 2017, and titled “SACRIFICIAL TEST PADS FOR INLINE TEST ACCESS,” the disclosure of which is expressly incorporated by reference herein in its entirety.

### BACKGROUND

### Field

Aspects of the present disclosure relate to semiconductor devices, and more particularly to sacrificial test pads that allow inline test access to portions of an integrated circuit (IC) hidden by manufacturing or test equipment.

### Background

The process flow for semiconductor fabrication of integrated circuits may include front-end-of-line (FEOL), middle-of-line (MOL), and back-end-of-line (BEOL) processes. The front-end-of-line processes may include wafer preparation, isolation, well formation, gate patterning, spacer, extension and source/drain implantation, silicide formation, and dual stress liner formation. The middle-of-line process may include gate contact formation. Middle-of-line layers may include, but are not limited to, middle-of-line contacts, vias or other layers within close proximity to the semiconductor device transistors or other like active devices. The back-end-of-line processes may include a series of wafer processing steps for interconnecting the semiconductor devices created during the front-end-of-line and middle-of-line processes. Successful fabrication of modern semiconductor chip products involves an interplay between the materials and the processes employed.

During the process flow for integrated circuit manufacturing, portions of an integrated circuit may be inaccessible. That is, testing equipment or manufacturing equipment may block access to portions, such as one side of the integrated circuit. The blocked access prevents testing of portions of the integrated circuit.

### SUMMARY

In one aspect of the present disclosure, a chip assembly is disclosed. The chip assembly includes a first die pad on a first side of the chip assembly. The first side of the chip assembly is obscured and inaccessible during testing of the chip assembly. The chip assembly also includes a second die pad on a second side of the chip assembly, opposite the first side. The chip assembly further includes a portion of a sacrificial test pad on a sidewall of the chip assembly and electrically connected to the first die pad.

In another aspect of the present disclosure, a method of manufacturing a semiconductor device is disclosed. The method includes determining multiple die that are free of manufacturing defects based on a wafer probe. The method also includes placing the multiple die on a wafer or a panel to fabricate interconnects and to create a chip assembly, the chip assembly having pads on opposing sides. The method further includes testing both sides of the chip assembly from a same side of the chip assembly.

Another aspect of the present disclosure is directed to a chip assembly. The chip assembly includes a die pad on a first side of the chip assembly. The chip assembly also includes a portion of a means for testing on a sidewall of the chip assembly and electrically connected to the die pad.

This has outlined, rather broadly, the features and technical advantages of the present disclosure in order that the detailed description that follows may be better understood. Additional features and advantages of the disclosure will be described below. It should be appreciated by those skilled in the art that this disclosure may be readily utilized as a basis for modifying or designing other structures for carrying out the same purposes of the present disclosure. It should also be realized by those skilled in the art that such equivalent constructions do not depart from the teachings of the disclosure as set forth in the appended claims. The novel features, which are believed to be characteristic of the disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates a perspective view of a semiconductor wafer in an aspect of the present disclosure.

FIG. 2 illustrates a cross-sectional view of a die in accordance with an aspect of the present disclosure.

FIG. 3 illustrates an example of an integrated circuit according to aspects of the present disclosure

FIGS. 4 and 5 illustrate examples of manufacturing flows for chip assembly according to aspects of the disclosure.

FIG. 6 illustrates an example of a top down view of a carrier comprising multiple chip assemblies according to aspects of the present disclosure.

FIGS. 7A, 7B, and 8 illustrate side views of chip assemblies according to aspects of the present disclosure.

FIGS. 9 and 10 illustrate examples of chip assemblies according to aspects of the present disclosure.

FIG. 11 is a process flow diagram illustrating a method for fabricating a manufacturing a semiconductor device according to aspects of the present disclosure.

FIG. 12 is a block diagram showing an exemplary wireless communication system in which a configuration of the disclosure may be advantageously employed.

FIG. 13 is a block diagram illustrating a design workstation used for circuit, layout, and logic design of a semiconductor component according to one configuration.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. It will be apparent to those skilled in the art, however, that these concepts may be practiced without these specific details. In some instances, well-known structures and components are shown in block diagram form in order to avoid obscuring such concepts. As described herein, the use of the term “and/or” is intended to represent an “inclusive OR”, and the use of the term “or” is intended to represent an “exclusive OR”.

In some conventional systems, during fabrication (e.g., manufacturing) of a semiconductor device, such as a fan out wafer level package, both sides of a system on chip (SOC) wafer are accessible such that both sides of the system on chip wafer may be tested. In other conventional systems, one side of the system on chip wafer is covered by manufacturing or test equipment, such as a carrier or panel. In this scenario, one side of the system on chip wafer is inaccessible for testing during the manufacturing process, such that both sides of the chip assembly cannot be tested during the manufacturing flow. The inability to test both sides of the chip assembly prevents elimination of defective units before the next manufacturing step, thereby, reducing the final product yield and increasing manufacturing cost.

During fabrication of a semiconductor device, such as a fan out wafer level package, the system on chip wafer is probed to find the good die at a wafer probe step. The good die are singulated from the system on chip wafer and the singulated die are placed on a carrier at a die placement step. After the die placement, the wafer is reconstituted and one or more metal processes are performed to form the fan out wafer. For the fan out wafer, only one side is accessible for testing device pads (e.g., ball grid array (BGA) pads). The inaccessible side includes other device pads (e.g., package-on-package (POP) pads) that are inaccessible due to the presence of manufacturing equipment, test equipment, or other equipment. It is desirable to allow for testing of both sides during the manufacturing process. In one configuration, sacrificial test pads are provided on one side of the chip assembly to allow access to the inaccessible side of the chip assembly (e.g., integrated circuit).

Aspects of the present disclosure are not limited to fan out wafers and contemplate any type of semiconductor/integrated circuit assembly (e.g., in wafer form or panel form), where one side of the die is not accessible for testing. The semiconductor assembly may be referred to as a chip assembly. In one configuration, the semiconductor assembly is a component of a system in package. Additionally, aspects of the present disclosure are not limited to the accessible side comprising BGA pads and the inaccessible side comprising POP pads. Different sides of a chip assembly may be accessible/inaccessible based on the packaging solution (e.g., silicon wafer integrated fan out technology (SWIFT) or integrated fan out (InFO), etc.)

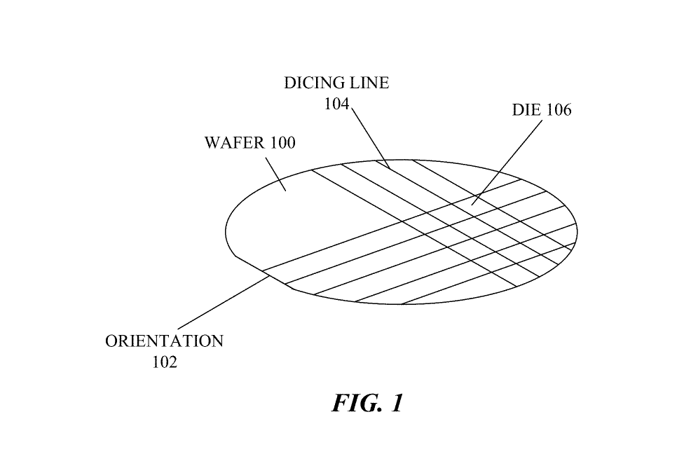

FIG. 1 illustrates a perspective view of a semiconductor wafer in an aspect of the present disclosure. A wafer 100 may be a semiconductor wafer, or may be a substrate material with one or more layers of semiconductor material on a surface of the wafer 100. When the wafer 100 is a semiconductor material, it may be grown from a seed crystal using the Czochralski process, where the seed crystal is dipped into a molten bath of semiconductor material and slowly rotated and removed from the bath. The molten material then crystalizes onto the seed crystal in the orientation of the crystal.

The wafer 100 may be silicon or a compound material, such as gallium arsenide (GaAs) or gallium nitride (GaN), a ternary material such as indium gallium arsenide (InGaAs), quaternary materials, or any material that can be a substrate material for other semiconductor materials. Although many of the materials may be crystalline in nature, polycrystalline or amorphous materials may also be used for the wafer 100.

The wafer 100, or layers that are coupled to the wafer 100, may be supplied with materials that make the wafer 100 more conductive. For example, and not by way of limitation, a silicon wafer may have phosphorus or boron added to the wafer 100 to allow for electrical charge to flow in the wafer 100. These additives are referred to as dopants, and provide extra charge carriers (either electrons or holes) within the wafer 100 or portions of the wafer 100. By selecting the areas where the extra charge carriers are provided, which type of charge carriers are provided, and the amount (density) of additional charge carriers in the wafer 100, different types of electronic devices may be formed in or on the wafer 100.

The wafer 100 has an orientation 102 that indicates the crystalline orientation of the wafer 100. The orientation 102 may be a flat edge of the wafer 100 as shown in FIG. 1, or may be a notch or other indicia to illustrate the crystalline orientation of the wafer 100. The orientation 102 may indicate the Miller Indices for the planes of the crystal lattice in the wafer 100.

Once the wafer 100 has been processed as desired, the wafer 100 is divided up along dicing lines 104. The dicing lines 104 indicate where the wafer 100 is to be broken apart or separated into pieces. The dicing lines 104 may define the outline of the various integrated circuits that have been fabricated on the wafer 100.

Once the dicing lines 104 are defined, the wafer 100 may be sawn or otherwise separated into pieces to form die 106. Each of the die 106 may be an integrated circuit with many devices or may be a single electronic device. The physical size of the die 106, which may also be referred to as a chip or a semiconductor chip, depends at least in part on the ability to separate the wafer 100 into certain sizes, as well as the number of individual devices that the die 106 is designed to contain.

Once the wafer 100 has been separated into one or more die 106, the die 106 may be mounted into packaging to allow access to the devices and/or integrated circuits fabricated on the die 106. Packaging may include single in-line packaging, dual in-line packaging, motherboard packaging, flip-chip packaging, indium dot/bump packaging, or other types of devices that provide access to the die 106. The die 106 may also be directly accessed through wire bonding, probes, or other connections without mounting the die 106 into a separate package.

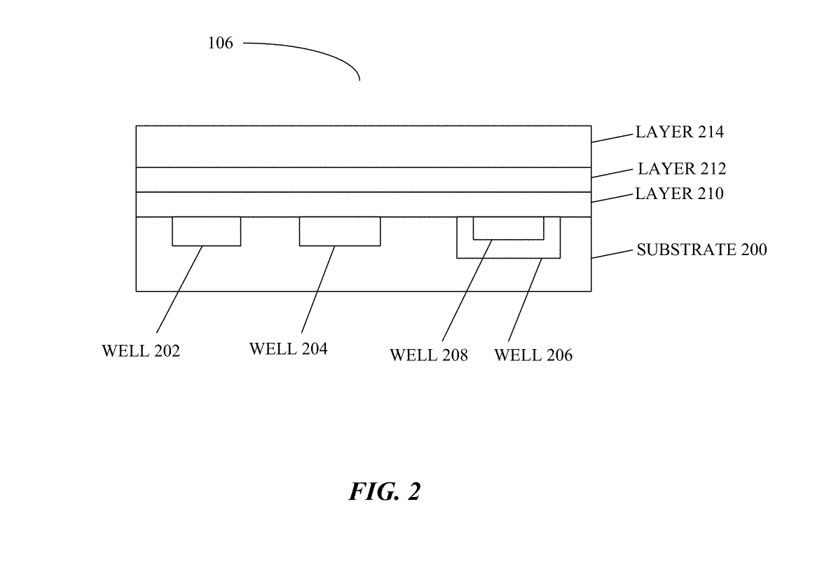

FIG. 2 illustrates a cross-sectional view of a die 106 in accordance with an aspect of the present disclosure. In the die 106, there may be a substrate 200, which may be a semiconductor material and/or may act as a mechanical support for electronic devices. The substrate 200 may be a doped semiconductor substrate, which has either electrons (designated N-channel) or holes (designated P-channel) charge carriers present throughout the substrate 200. Subsequent doping of the substrate 200 with charge carrier ions/atoms may change the charge carrying capabilities of the substrate 200.

Within a substrate 200 (e.g., a semiconductor substrate), there may be wells 202 and 204, or wells 202 and/or 204 may be fin structures of a fin structured FET (FinFET). A diffusion built inside the well may be the source and/or drain of a field-effect transistor (FET), Wells 202 and/or 204 may also be other devices (e.g., a resistor, a capacitor, a diode, or other electronic devices) depending on the structure and other characteristics of the wells 202 and/or 204 and the surrounding structure of the substrate 200.

The semiconductor substrate may also have a well 206 and a well 208. The well 208 may be completely within the well 206, and, in some cases, may form a bipolar junction transistor (BJT). The well 206 may also be used as an isolation well to isolate the well 208 from electric and/or magnetic fields within the die 106.

Layers (e.g., 210 through 214) may be added to the die 106. The layer 210 may be, for example, an oxide or insulating layer that may isolate the wells (e.g., 202-208) from each other or from other devices on the die 106. In such cases, the layer 210 may be silicon dioxide, a polymer, a dielectric, or another electrically insulating layer. The layer 210 may also be an interconnection layer, in which case it may comprise a conductive material such as copper, tungsten, aluminum, an alloy, or other conductive or metallic materials.

The layer 212 may also be a dielectric or conductive layer, depending on the desired device characteristics and/or the materials of the layers (e.g., 210 and 214). The layer 214 may be an encapsulating layer, which may protect the layers (e.g., 210 and 212), as well as the wells 202-208 and the substrate 200, from external forces. For example, and not by way of limitation, the layer 214 may be a layer that protects the die 106 from mechanical damage, or the layer 214 may be a layer of material that protects the die 106 from electromagnetic or radiation damage.

Electronic devices designed on the die 106 may comprise many features or structural components. For example, the die 106 may be exposed to any number of methods to impart dopants into the substrate 200, the wells 202-208, and, if desired, the layers (e.g., 210-214). For example, and not by way of limitation, the die 106 may be exposed to ion implantation, deposition of dopant atoms that are driven into a crystalline lattice through a diffusion process, chemical vapor deposition, epitaxial growth, or other methods. Through selective growth, material selection, and removal of portions of the layers (e.g., 210-214), and through selective removal, material selection, and dopant concentration of the substrate 200 and the wells 202-208, many different structures and electronic devices may be formed within the scope of the present disclosure.

Further, the substrate 200, the wells 202-208, and the layers (e.g., 210-214) may be selectively removed or added through various processes. Chemical wet etching, chemical mechanical planarization (CMP), plasma etching, photoresist masking, damascene processes, and other methods may create the structures and devices of the present disclosure.

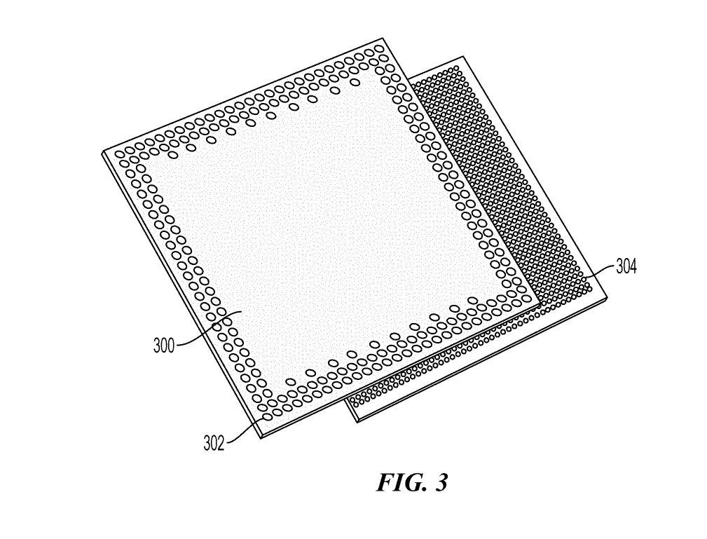

FIG. 3 illustrates an example of an integrated circuit 300 according to aspects of the present disclosure. As shown in FIG. 3, one side of the system on integrated circuit 300 comprises package-on-package (POP) pads 302. In one configuration, the POP pads 302 connect to a memory device, such as dynamic random-access memory (DRAM). The integrated circuit 300 also comprises ball grid array (BGA) pads 304. In the present application, the term pad may be used interchangeably with bump. The ball grid array pads 304 are on a side of the system on integrated circuit 300 that is opposite to the side having the package-on-package pads 302.

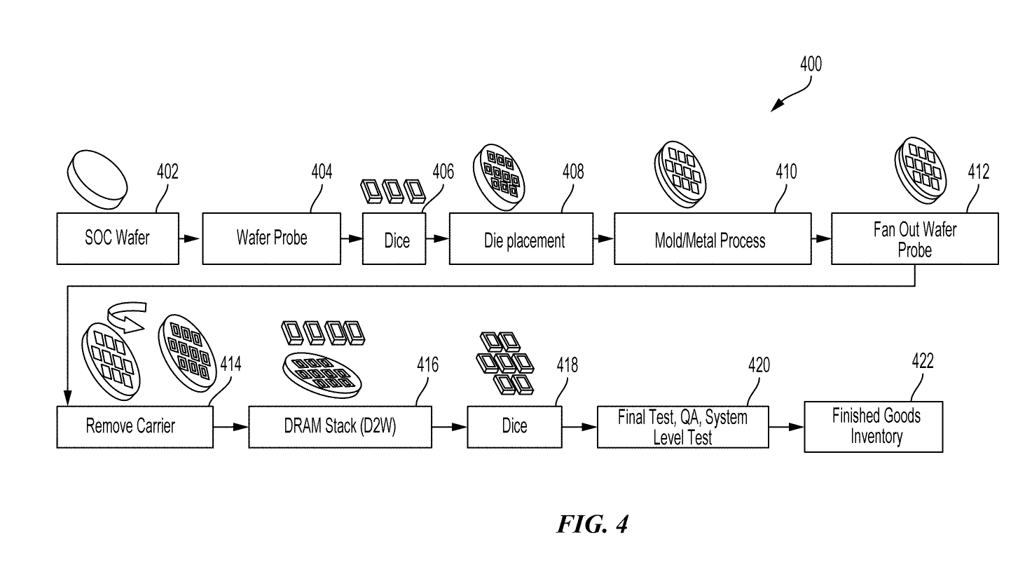

FIG. 4 illustrates a manufacturing flow 400 for a chip assembly according to an aspect of the disclosure. The manufacturing flow 400 of FIG. 4 may be referred to as a system on chip (SOC) wafer level fan out flow. At block 402, a wafer, such as an SOC wafer, is provided for manufacturing. At block 404, the SOC wafer is probed to find good one or more die. At block 406, the good die are diced from the wafer and placed on a carrier (block 408). At block 410, one or more metal processes are performed to form a reconstituted wafer and the reconstituted wafer is tested (block 412). In conventional systems, only one side of the chip assembly is available for testing. For example, only the BGA pads may be accessible for testing and the POP pads may be inaccessible. In one configuration, to provide access to the inaccessible side of the chip assembly, sacrificial test pads (not shown) are electronically connected to the pads/bumps on the inaccessible side of the chip assembly. In this configuration, the sacrificial test pads extend upwards to be accessible.

According to aspects of the present disclosure, both sides of the chip assembly are tested (block 412). That is, the accessible pads and the inaccessible side are tested. In one configuration, in addition to, or alternate from, using test equipment on the sacrificial test pads, the sacrificial test pads may be connected to other devices, such as DRAM, for testing. At block 414, after testing each die, the die are removed from the carrier. The die that passed the tests may be further used for the additional steps of the manufacturing process.

For example, at block 416, DRAM may be stacked on the good die. Furthermore, at block 418, the DRAM stacked die may be diced from the wafer, removing the sacrificial test pads. At block 420, quality procedures such as final tests, quality assurance, and/or system level tests, may be performed on the DRAM stacked die. Finally, at block 422, the DRAM stacked die that passed quality procedures are used as the finished goods for inventory.

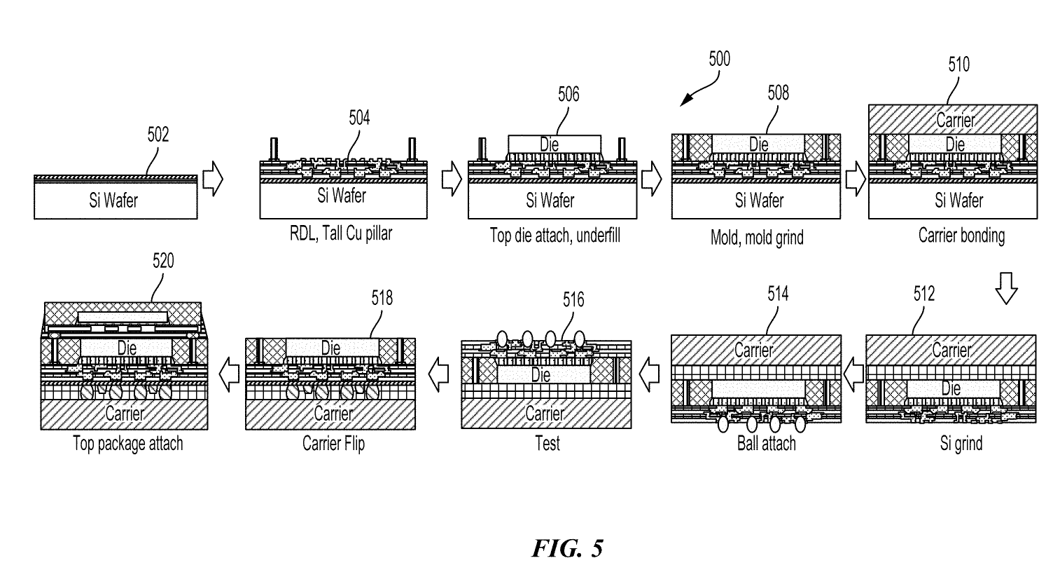

FIG. 5 illustrates a manufacturing flow 500 for a chip assembly according to an aspect of the disclosure. The manufacturing flow 500 of FIG. 5 may be referred to as silicon wafer integrated fan out technology (SWIFT) (pre-stack assembly) flow. At block 502, a wafer, such as a silicon (Si) wafer, is provided for manufacturing. At block 504, a redistribution layer and tall copper (Cu) pillars are formed on the wafer. At block 506, the top die is attached to the wafer and the wafer is underfilled. Additionally, at block 508, molding and mold grinding are performed. The carrier is bonded (block 510) and a silicon grind is performed (block 512). At block 514, balls (e.g., BGA pads) are attached. A test may be performed after the balls are attached.

In conventional systems, die to die package-on-package (POP) pads are not accessible at the test stage and only BGA pads are contacted. As previously discussed, it is desirable to access both sides of the die to test both sides of a chip assembly (e.g., perform a complete test). According to aspects of the present disclosure, the sacrificial test pads (not shown) are fabricated to provide access to the die to die POP pads that are not accessible at the test stage such that both sides of the chip assembly are tested (block 516). The sacrificial test pads are connected to the die to die POP pads via an electrical connection, such as conductive trace. At block 518, after testing, a carrier flip is performed and the top package is attached (block 520).

As previously discussed, conventional manufacturing processes do not allow access to pads, such as POP pads, for testing during the manufacturing process. At best, in conventional systems, POP pads are tested after the die are removed from a wafer. Testing the POP pads after the die has been removed may increase costs and reduce the speed of the manufacturing process. Aspects of the present disclosure are directed to providing sacrificial test pads for test access to the inaccessible side of the chip assembly (e.g., access to the POP pads). The sacrificial test pads are placed on the same side of the inaccessible pads and extend upwards to the same side as the accessible pads (e.g., BGA pads), such that the sacrificial test pads are accessible during the manufacturing testing. The sacrificial test pads allow for complete access to the input/output of the die so that both sides of the chip assembly may be tested. Aspects of the present disclosure are not limited to the SWIFT flow and/or SOC wafer level fan out flow. Of course, other flows and/or assemblies are contemplated where one side of the die is not accessible for testing. For example, the chip assembly may be manufactured on a laminate panel.

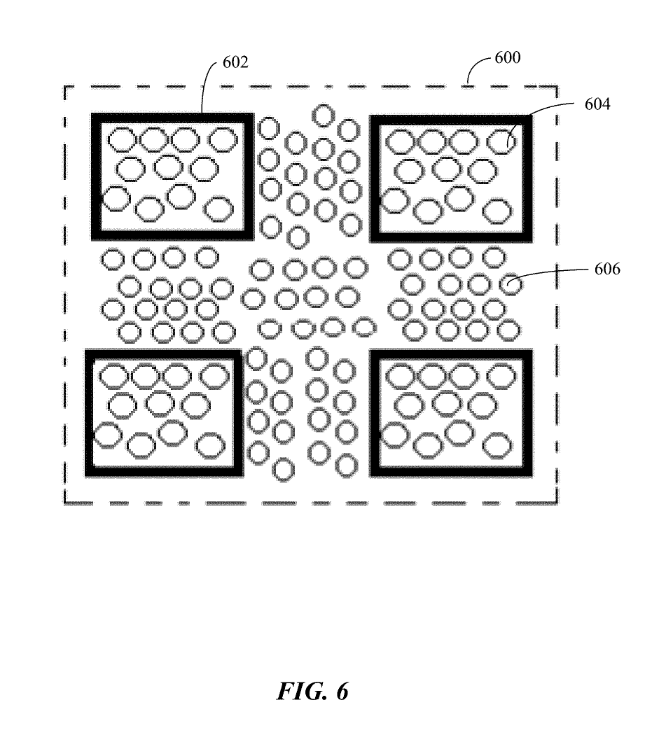

FIG. 6 illustrates an example of a top down view of a carrier 600 comprising multiple chip assemblies (e.g., die) 602 according to aspects of the present disclosure. As shown in FIG. 6, BGA pads 604 are visible, such that the BGA pads 604 are accessible for testing. Furthermore, package-on-package (POP) pads (not shown) are on a side of each die that is opposite to the side comprising the BGA pads 604. As such, the POP pads are inaccessible using conventional testing and fabrication techniques. According to aspects of the present disclosure, sacrificial test pads 606 are connected to the POP pads. In one configuration, the sacrificial test pads 606 extend upwards in the scribe lines (e.g., adjacent to the sidewall of each die 602) to provide access to the POP pads. That is, due to the sacrificial test pads 606, both the BGA pads 604 and the POP pads are accessible from one side of the chip assembly.

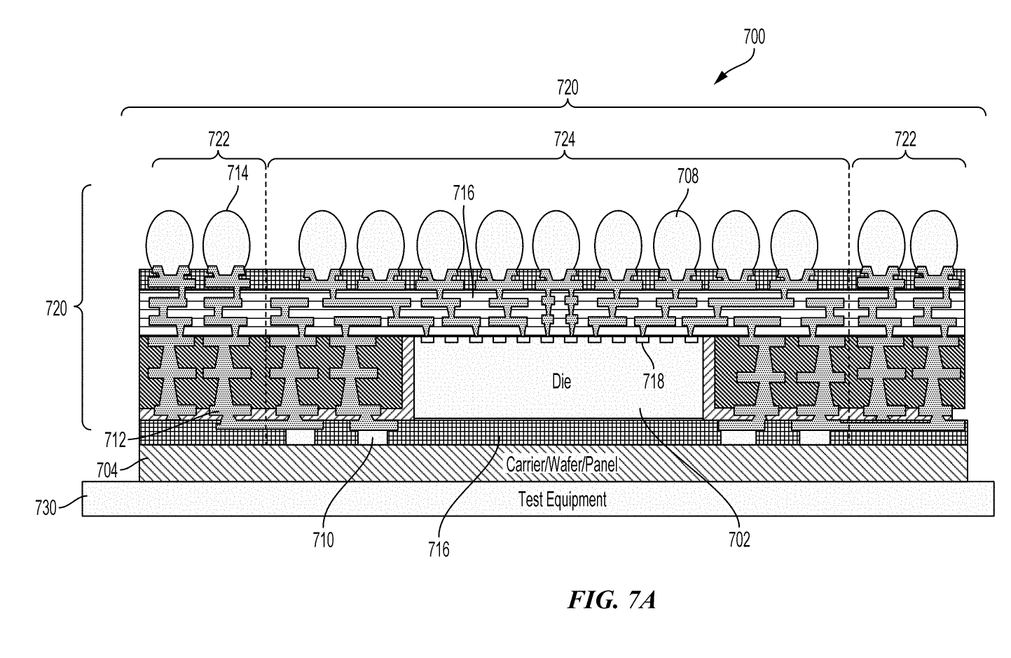

FIG. 7A illustrates a side view of a chip assembly 700 according to aspects of the present disclosure. As shown in FIG. 7A, packaging material 716 sits on a carrier 704 and a die 702 is placed on the packaging material 716. Packaging material 716 may also be placed on top of the die 702. The packaging material 716 may be a mold compound, insulating material, and/or laminate. Of course, the packaging material 716 may change based on the manufacturing process. The carrier 704 may also be a wafer or a panel. The carrier 704 may be placed on top of test equipment 730.

In the present example, only ball grid array (BGA) pads 708 are accessible for testing. In one configuration, conductive (e.g., metal) connections 712 are connected to pads 710 (e.g., package-on-package (POP) pads) on a side of the chip assembly 700 that is opposite to the side having the BGA pads 708. The conductive connections 712 extend upward between the die 702 to be accessible during testing. That is, the conductive connections 712 may extend upward in a scribe line region of the chip assembly 700. The conductive connections 712 are connected to sacrificial test pads 714. In the present example, the conductive connections 712 for all of the sacrificial test pads 714 are not shown, as the present example is a cross section of a portion of the chip assembly 700. That is, each sacrificial test pad 714 is connected to one of the pads 710 via a conductive connection 712.

As shown in FIG. 7A, each BGA pad 708 is connected to a die pad 718 via a conductive connection 712. During testing, the entire chip assembly area 720 is considered to be the device under test. After testing is complete, during a stage of the manufacturing process, a scribe line region 722 containing the sacrificial test pads 714 and other material is removed such that only a product (e.g., module) 724 remains.

Other chip assemblies may be adjacent to each scribe line region 722. That is, multiple die with sacrificial test pads may be placed together on a carrier. After testing, the sacrificial test pads are removed, such that the final module remains for each die. FIG. 7B illustrates an example of the chip assembly area 720 of FIG. 7A with other chip assembly areas 750. As shown in FIG. 7B, multiple die 702 with sacrificial test pads 714 can be placed together on a carrier 704. The sacrificial test pads 714 are fabricated within a boundary 722 (e.g., scribe line region) between adjacent die 702. After testing is complete, the area in the boundary 722 is removed. That is, the sacrificial test pads 714 and other material in the boundary 722 are removed, such that only a final module 724 remains for each die.

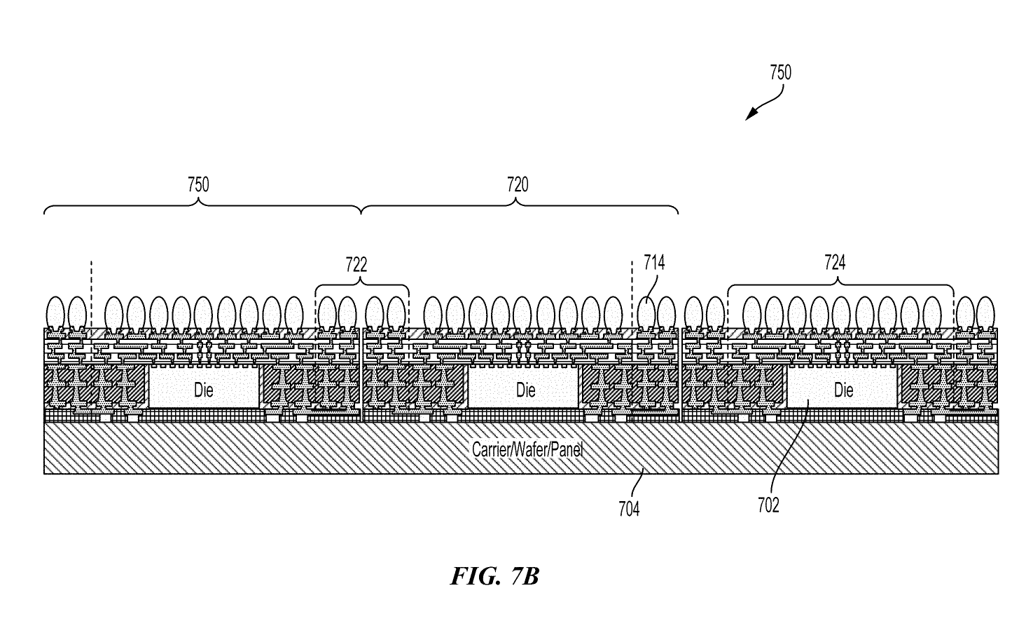

FIG. 8 illustrates a side view of a chip assembly 800 according to aspects of the present disclosure. As shown in FIG. 8, multiple die 802 are placed on a carrier 804. The carrier 804 may also be referred to as a wafer or a panel. The carrier 804 may be placed on top of test equipment 816. In one configuration, first pads 808 (e.g., BGA pads) and second pads 810 (e.g., POP pads) are connected to the die 802.

In the present example, only the first pads 808 are accessible for testing as access to the second pads 810 is blocked due to the placement of the carrier 804 and the test equipment 816. In one configuration, conductive (e.g., metal) connections 812 are connected to the second pads 810 on a side of the chip assembly 800 that is opposite to the side having the first pads 808. The conductive connections 812 extend upward between the die 802 to be accessible during testing. In one configuration, the conductive connections 812 extend upward in a scribe line region. The conductive connections 812 are connected to sacrificial test pads 814.

Aspects of the present disclosure are contemplated for different types of die assemblies, such as a wafer or panel. In the wafer assembly, the die is placed on the wafer. The layer below the die may have been prepared (e.g., etched) prior to the die placement or after the die placement. For the wafer assembly, the area around the die may be built up by plating, etching, and drilling. In the panel assembly, the area around the die may be built prior to the die placement. The sacrificial test pads expand the assembly regardless of the type of assembly. Aspects of the present disclosure are not limited to using sacrificial test pads with only wafer or panel assemblies and are contemplated for other types of assemblies.

Furthermore, aspects of the present disclosure are not limited to chip assemblies having only an inaccessible bottom side. Based on the packaging solution (e.g., silicon wafer integrated fan out technology (SWIFT), integrated fan out (InFO)), different sides of the chip assembly are inaccessible. The sacrificial test pads are contemplated for any side of the chip assembly.

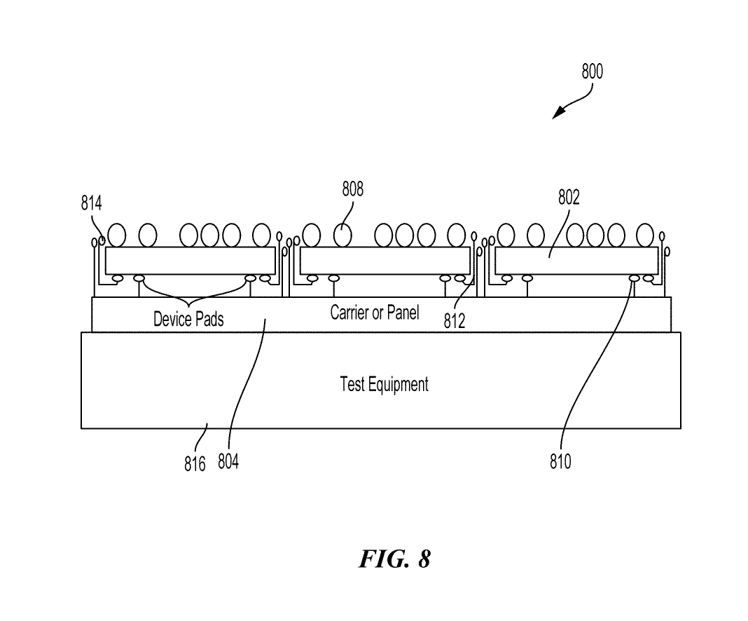

FIG. 9 illustrates an example of an integrated fan out chip assembly 900 having an inaccessible top side. As shown in FIG. 9, multiple die 902 are placed on a carrier 906. In this example, each die 902 is “face up,” such that at the carrier level, top side pads 904 are inaccessible while the bottom side pads (not shown) are accessible. In one configuration, sacrificial test pads (not shown) are connected to the top side pads 904 to provide access to the top side pads 904.

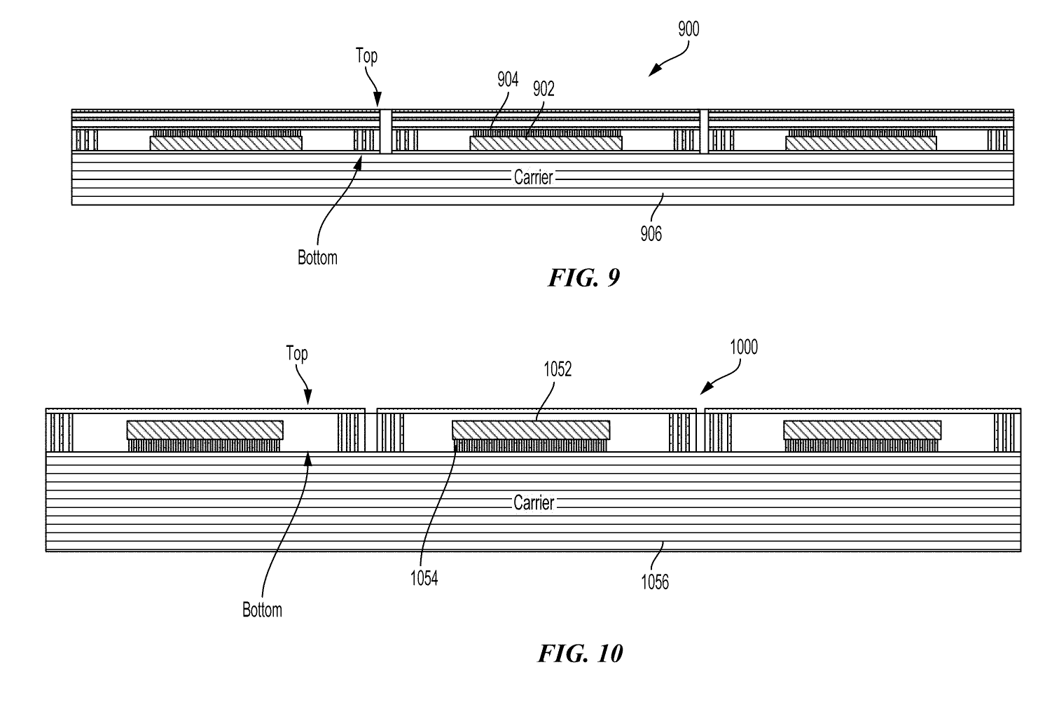

FIG. 10 illustrates an example of a silicon wafer integrated fan out chip assembly 1000 having an inaccessible bottom side. As shown in FIG. 10, multiple die 1052 are placed on a carrier 1056. In this example, each die 1052 is “face down,” such that at the carrier level, bottom side pads 1054 are inaccessible. In one configuration, sacrificial test pads (not shown) are connected to the bottom side pads 1054 to provide access to the bottom side pads 1054.

In one configuration, the conductive material connected to the sacrificial test pads is on a sidewall of the chip assembly and/or extends upwards adjacent to the sidewall of the chip assembly. The sidewall is adjacent to a top side and bottom side of the chip assembly. After the area including the sacrificial test pads is removed, a portion of the conductive material (e.g., sacrificial test pads) remains. In one configuration, the conductive material is referred to as a conductive trace.

According to an aspect of the present disclosure, a chip assembly is described. The chip assembly may include a die pad on a first side of the chip assembly. The chip assembly may also include a means for testing or a portion of a means for testing on a sidewall of the chip assembly. The means for testing may be electrically connected to the die pad. The means for testing may be, for example, the sacrificial test pads 606, 714, 814, as shown in FIGS. 6, 7A, 7B, and 8. In another aspect, the aforementioned means may be any module, layer or apparatus configured to perform the functions recited by the aforementioned means.

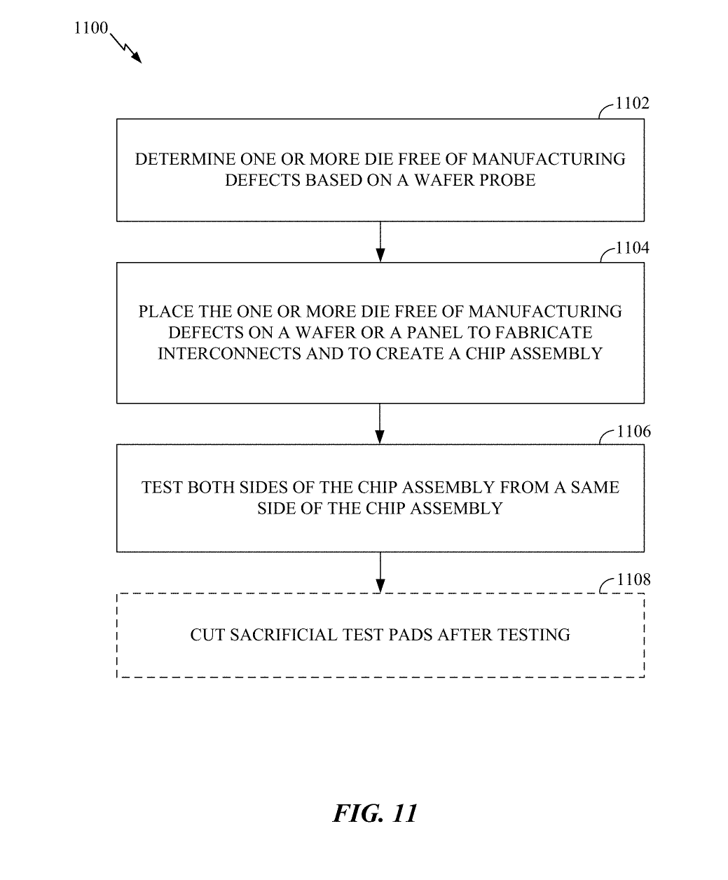

FIG. 11 is a flow diagram for a method 1100 of manufacturing a semiconductor device according to aspects of the present disclosure. As shown in FIG. 11, at block 1102, during manufacturing, a wafer probe is performed to determine one or more die free of manufacturing defects. At block 1104, the one or more die that are free of manufacturing defects are placed on a wafer (e.g., panel) to fabricate interconnects and to create a chip assembly. In one configuration the chip assembly has pads (e.g., ball grid array (BGA) pads and package-on-package (POP) pads) on opposing sides. At block 1106, both sides of the chip assembly are tested from a same side of the chip assembly. In one configuration, both the BGA pads and the POP pads are tested from the same side, such as the side of the chip assembly comprising the BGA pads. In one configuration, one of the pads of the chip assembly is on an inaccessible side of the chip assembly and the inaccessible pads are tested via sacrificial test pads. At block 1108, in an optional configuration, after testing, sacrificial test pads are cut.

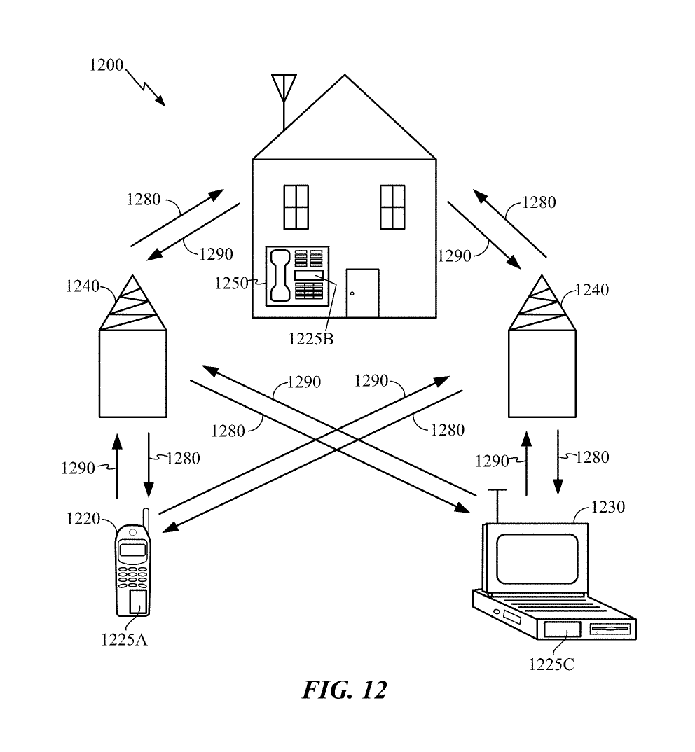

FIG. 12 is a block diagram showing an exemplary wireless communication system 1200 in which chip assemblies with sacrificial test pads may be advantageously employed. For purposes of illustration, FIG. 12 shows three remote units 1220, 1230, and 1250 and two base stations 1240. It will be recognized that wireless communication systems may have many more remote units and base stations. Remote units 1220, 1230, and 1250 include IC devices 1225A, 1225C, and 1225B that include the disclosed semiconductor device. It will be recognized that other devices may also include the semiconductor device, such as the base stations, switching devices, and network equipment. FIG. 12 shows forward link signals 1280 from the base station 1240 to the remote units 1220, 1230, and 1250 and reverse link signals 1290 from the remote units 1220, 1230, and 1250 to base stations 1240.

In FIG. 12, remote unit 1220 is shown as a mobile telephone, remote unit 1230 is shown as a portable computer, and remote unit 1250 is shown as a fixed location remote unit in a wireless local loop system. For example, the remote units 1220, 1230, and 1250 may be a mobile phone, a hand-held personal communication systems (PCS) unit, a portable data unit such as a personal digital assistant (PDA), a GPS enabled device, a navigation device, a set top box, a music player, a video player, an entertainment unit, a fixed location data unit such as a meter reading equipment, or other devices that store or retrieve data or computer instructions, or combinations thereof. Although FIG. 12 illustrates remote units according to the aspects of the disclosure, the disclosure is not limited to these exemplary illustrated units. Aspects of the disclosure may be suitably employed in many devices, which include the disclosed semiconductor components, such as the chip assemblies tested with sacrificial test pads disclosed above.

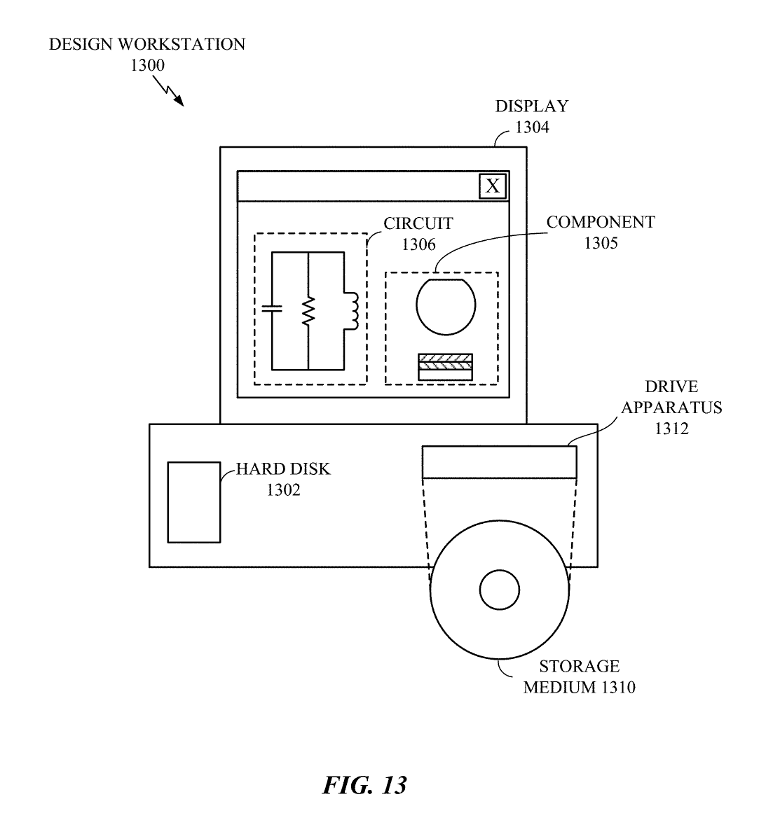

FIG. 13 is a block diagram illustrating a design workstation used for circuit, layout, and logic design of a semiconductor component, such as the chip assemblies tested with sacrificial test pads disclosed above. A design workstation 1300 includes a hard disk 1302 containing operating system software, support files, and design software such as Cadence or OrCAD. The design workstation 1300 also includes a display 1304 to facilitate design of a circuit 1306 or a semiconductor component 1305 such as a semiconductor device with sacrificial test pads. A storage medium 1310 is provided for tangibly storing the design of the circuit 1306 or the semiconductor component 1305. The design of the circuit 1306 or the semiconductor component 1305 may be stored on the storage medium 1310 in a file format such as GDSII or GERBER. The storage medium 1310 may be a CD-ROM, DVD, hard disk, flash memory, or other appropriate device. Furthermore, the design workstation 1300 includes a drive apparatus 1312 for accepting input from or writing output to the storage medium 1310.

Data recorded on the storage medium 1310 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1310 facilitates the design of the circuit 1306 or the semiconductor component 1305 by decreasing the number of processes for designing semiconductor wafers.

For a firmware and/or software implementation, the methodologies may be implemented with modules (e.g., procedures, functions, and so on) that perform the functions described herein. A machine-readable medium tangibly embodying instructions may be used in implementing the methodologies described herein. For example, software codes may be stored in a memory and executed by a processor unit. Memory may be implemented within the processor unit or external to the processor unit. As used herein, the term “memory” refers to types of long term, short term, volatile, nonvolatile, or other memory and is not to be limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include RAM, ROM, EEPROM, CD-ROM or other optical disk storage, magnetic disk storage or other magnetic storage devices, or other medium that can be used to store desired program code in the form of instructions or data structures and that can be accessed by a computer; disk and disc, as used herein, includes compact disc (CD), laser disc, optical disc, digital versatile disc (DVD), floppy disk and Blu-ray disc where disks usually reproduce data magnetically, while discs reproduce data optically with lasers. Combinations of the above should also be included within the scope of computer-readable media.

In addition to storage on computer readable medium, instructions and/or data may be provided as signals on transmission media included in a communication apparatus. For example, a communication apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions and alterations can be made herein without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above and below may refer to sides of a substrate or electronic device. Moreover, the scope of the present application is not intended to be limited to the particular configurations of the process, machine, manufacture, composition of matter, means, methods and steps described in the specification and in Appendix A. As one of ordinary skill in the art will readily appreciate from the disclosure, processes, machines, manufacture, compositions of matter, means, methods, or steps, presently existing or later to be developed that perform substantially the same function or achieve substantially the same result as the corresponding configurations described herein and in Appendix A may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the disclosure herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure herein may be implemented or performed with a general-purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein and in Appendix A. A general-purpose processor may be a microprocessor, but in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the disclosure may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

In one or more exemplary designs, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can include RAM, ROM, EEPROM, CD-ROM or other optical disk storage, magnetic disk storage or other magnetic storage devices, or any other medium that can be used to carry or store specified program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD) and Blu-ray disc where disks usually reproduce data magnetically, while discs reproduce data optically with lasers. Combinations of the above should also be included within the scope of computer-readable media.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover: a; b; c; a and b; a and c; b and c; and a, b and c. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112, sixth paragraph, unless the element is expressly recited using the phrase “means for” or, in the case of a method claim, the element is recited using the phrase “a step for.”

What is claimed is:

1. A chip assembly, comprising:
a first die pad on a first side of the chip assembly, the first side obscured and inaccessible during testing of the chip assembly;
a second die pad on a second side of the chip assembly, opposite the first side; and
at least a portion of a sacrificial test pad on a sidewall of the chip assembly and electrically connected to the first die pad.

2. The chip assembly of claim 1, in which the sidewall is adjacent to the first side and the second side of the chip assembly.

3. The chip assembly of claim 1, in which the first die pad comprises a package-on-package (POP) pad and the second die pad comprises a ball grid array (BGA) pad.

4. The chip assembly of claim 1, in which the chip assembly is a component of a system in package.

5. The chip assembly of claim 1, in which the portion of the sacrificial test pad comprises a conductive trace electrically connected to the first die pad.

6. The chip assembly of claim 1, in which the chip assembly is manufactured on a reconstituted wafer or a laminate panel.

7. The chip assembly of claim 1, integrated into a mobile phone, a set top box, a music player, a video player, an entertainment unit, a navigation device, a computer, a hand-held personal communication systems (PCS) unit, a portable data unit, and/or a fixed location data unit.

8. A method of manufacturing a semiconductor device, comprising:
determining a plurality of die free of manufacturing defects based on a wafer probe;
placing the plurality of die on a wafer or a panel to fabricate interconnects and to create a chip assembly, the chip assembly having pads on opposing sides; and
testing both sides of the chip assembly from a same side of the chip assembly.

9. The method of claim 8, in which the testing further comprises testing an inaccessible side of the chip assembly via sacrificial test pads.

10. The method of claim 9, further comprising cutting the sacrificial test pads after testing.

11. The method of claim 8, in which the pads on a first side of the chip assembly comprise package-on-package (POP) pads and the pads on a second side of the chip assembly comprise ball grid array (BGA) pads.

12. The method of claim 8, further comprising integrating the semiconductor device into a mobile phone, a set top box, a music player, a video player, an entertainment unit, a navigation device, a computer, a hand-held personal communication systems (PCS) unit, a portable data unit, and/or a fixed location data unit.

13. A chip assembly, comprising:
a die pad on a first side of the chip assembly; and
at least a portion of a means for testing on a sidewall of the chip assembly and electrically connected to the die pad.

14. The chip assembly of claim 13, in which the sidewall is adjacent to the first side of the chip assembly.

15. The chip assembly of claim 13, in which the portion of the means for testing on the sidewall of the chip assembly is proximate to a ball grid array (BGA) assembly electrically connected to die pads on the first side of the chip assembly.

16. The chip assembly of claim 13, in which the chip assembly is a component of a system in package.

17. The chip assembly of claim 13, in which the portion of the means for testing comprises a means for connecting to the die pad.

18. The chip assembly of claim 13, in which the first side is obscured during test.

19. The chip assembly of claim 13, integrated into a mobile phone, a set top box, a music player, a video player, an entertainment unit, a navigation device, a computer, a hand-held personal communication systems (PCS) unit, a portable data unit, and/or a fixed location data unit.
